(19) United States
(12) Patent Application Publication
(10) Pub. No.: US 2016/0293751 A1
(43) Pub. Date: Oct. 6, 2016

(54) Semiconductor Device with Gate Fins

(71) Applicant: Infineon Technologies Austria AG, Villach (AT)

(72) Inventors: Ralf Siemieniec, Villach (AT); David Laforet, Villach (AT)

(21) Appl. No.: 15/082,214

(22) Filed: Mar. 28, 2016

(30) Foreign Application Priority Data
Mar. 31, 2015 (DE) 102015104988.0

(51) Int. Cl. H01L 29/78; H01L 29/06; H01L 29/66; H01L 23/535; H01L 27/088; H01L 29/40; H01L 29/08

(52) U.S. Cl. CPC H01L 29/7811; H01L 29/404; H01L 29/0696; H01L 29/0856; H01L 23/535; H01L 27/088; H01L 29/7813; H01L 29/66712

(57) ABSTRACT

A semiconductor device includes gate fins extending from a first surface into a semiconductor portion. The gate fins include gate electrodes and are arranged along element lines, wherein longitudinal axes of the gate fins are parallel to the element lines. Column sections of the semiconductor portion separate the gate fins from each other along the element lines.

### PRIORITY CLAIM

This application claims priority to German Patent Application No. 10 2015 104 988.0 filed on 31 Mar. 2015, the content of said application incorporated herein by reference in its entirety.

### BACKGROUND

Power semiconductor devices, for examples IGFETs (insulated gate field effect transistors) are typically devices with a vertical load current flow between a first surface at a front side of a semiconductor die and a second surface on the back. In a blocking mode field electrode structures extending from the front side into the semiconductor die deplete a drift portion of the semiconductor die. The field electrode structures allow high dopant concentrations in the drift portion without adverse impact on the blocking capability. Higher dopant concentrations in the drift portion reduce the on-state resistance of the device.

It is desirable to provide reliable semiconductor devices with low parasitic capacitances.

### SUMMARY

According to an embodiment a semiconductor device includes gate fins extending from a first surface into a semiconductor portion. The gate fins include gate electrodes and are arranged along element lines, wherein longitudinal axes of the gate fins are parallel to the element lines. Column sections of the semiconductor portion separate the gate fins from each other along the element lines.

According to another embodiment a semiconductor device includes first and second gate fins extending from a first surface into a semiconductor portion, wherein the first gate fins are arranged along first element lines and the second gate fins are arranged along second element lines crossing the first element lines. The first and second gate fines include gate electrodes. First column sections of the semiconductor portion separate first gate fins from second gate fins at crossings of the first and second element lines. Field electrode structures extend from the first surface into the semiconductor portion. The field electrode structures include a field dielectric insulating spicular field electrodes from the semiconductor portion.

According to another embodiment, a method of manufacturing a semiconductor device includes forming gate fins that extend from a process surface into a semiconductor layer. The gate fins are arranged along element lines, wherein the gate fins are separated from each other along the element lines by column sections of the semiconductor layer. Gate contacts are formed that extend through a pre-metal dielectric on the process surface to gate electrodes formed in the gate fins. A gate wiring connecting the gate contacts is formed on the pre-metal dielectric.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1A is a schematic horizontal cross-sectional view of a portion of a semiconductor device including gate fins arranged along parallel element lines according to an embodiment.

FIG. 1B is a schematic vertical cross-sectional view of the semiconductor device portion of FIG. 1A along line B-B.

FIG. 1C is a schematic vertical cross-sectional view of the semiconductor device portion of FIG. 1A along line C-C.

FIG. 2A is a schematic horizontal cross-sectional view of a portion of a semiconductor device according to an embodiment related to stripe-shaped field electrode structures and gate fins arranged along parallel element lines.

FIG. 2B is a schematic horizontal cross-sectional view of a portion of a semiconductor device according to an embodiment related to field electrode structures with spicular field electrodes and gate fins arranged along parallel element lines.

FIG. 3A is a schematic diagram showing a transfer characteristic of a conventional device for discussing effects of the embodiments.

FIG. 3B is a schematic perspective view of a portion of a semiconductor device showing the electric field strength distribution in a conventional device for discussing effects of the embodiments.

FIG. 4A is a schematic horizontal cross-sectional view of a portion of a semiconductor device according to another embodiment including non-crossing gate fins arranged along element lines forming a grid with six gate gaps per mesh.

FIG. 4B is a schematic horizontal cross-sectional view of a portion of a semiconductor device including non-crossing gate fins arranged along element lines forming a grid according to an embodiment with eight gate gaps per mesh.

FIG. 4C is a schematic horizontal cross-sectional view of a portion of a semiconductor device including non-crossing gate fins arranged along element lines forming a grid according to an embodiment with ten gate gaps per mesh.

FIG. 4D is a schematic horizontal cross-sectional view of a portion of a semiconductor device including non-crossing gate fins arranged along element lines forming a grid according to an embodiment with twelve gate gaps per mesh.

FIG. 4E is a schematic horizontal cross-sectional view of a portion of a semiconductor device including non-crossing gate fins arranged along element lines forming a grid according to an embodiment with gate gaps at the nodes of the grid.

FIG. 4F is a schematic horizontal cross-sectional view of a portion of a semiconductor device including non-crossing gate fins arranged along element lines forming a grid according to an embodiment with discontinuous second element lines.

FIG. 4G is a schematic horizontal cross-sectional view of a portion of a semiconductor device including non-crossing gate fins according to an embodiment concerning gate fins arranged along a grid formed by zig-zag first element lines and discontinuous second element lines.

FIG. 4H is a schematic horizontal cross-sectional view of a portion of a semiconductor device including crossing gate fins according to an embodiment concerning gate fins arranged along a grid formed by zig-zag first element lines and discontinuous second element lines.

FIG. 5A is a schematic diagram showing small-signal reverse transfer characteristics Crss and small-signal output capacitance Coss of semiconductor devices with and without gate gaps for discussing effects of the embodiments.

FIG. 5B is a schematic diagram showing the gate voltage as a function of the gate charge for semiconductor devices with and without gate gaps for discussing effects of the embodiments.

FIG. 6A is a schematic horizontal cross-sectional view of a portion of a semiconductor device including gate fins arranged along element lines forming a grid according to a further embodiment.

FIG. 6B is a schematic vertical cross-sectional view of the semiconductor device portion of FIG. 6A along line B-B.

FIG. 6C is a schematic vertical cross-sectional view of the semiconductor device portion of FIG. 6A along line C-C.

FIG. 7A is a schematic plan view of a portion of a semiconductor substrate including spicular field electrodes for illustrating a method of manufacturing a semiconductor device according to a further embodiment.

FIG. 7B is a schematic vertical cross-sectional view of the semiconductor substrate portion of FIG. 7A along line B-B.

FIG. 8A is a schematic plan view of the semiconductor substrate portion of FIG. 7A, after forming separated gate trenches.

FIG. 8B is a schematic vertical cross-sectional view of the semiconductor substrate portion of FIG. 8A along line B-B.

FIG. 9A is a schematic plan view of the semiconductor substrate portion of FIG. 8A, after forming gate contacts electrically connected to gate electrodes formed in the gate trenches.

FIG. 9B is a schematic vertical cross-sectional view of the semiconductor substrate portion of FIG. 9A along line B-B.

FIG. 10A is a schematic plan view of the semiconductor substrate portion of FIG. 9A, after forming a gate wiring.

FIG. 10B is a schematic vertical cross-sectional view of the semiconductor substrate portion of FIG. 10A along line B-B.

FIG. 11A is a schematic plan view of the semiconductor substrate portion of FIG. 10A, after forming an inter-metal dielectric.

FIG. 11B is a schematic vertical cross-sectional view of the semiconductor substrate portion of FIG. 11A along line B-B.

FIG. 12 is a schematic circuit diagram of an electronic assembly according to an embodiment related to switched mode power supplies and motor drives.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude additional elements or features. The articles “a”, an and the are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The Figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

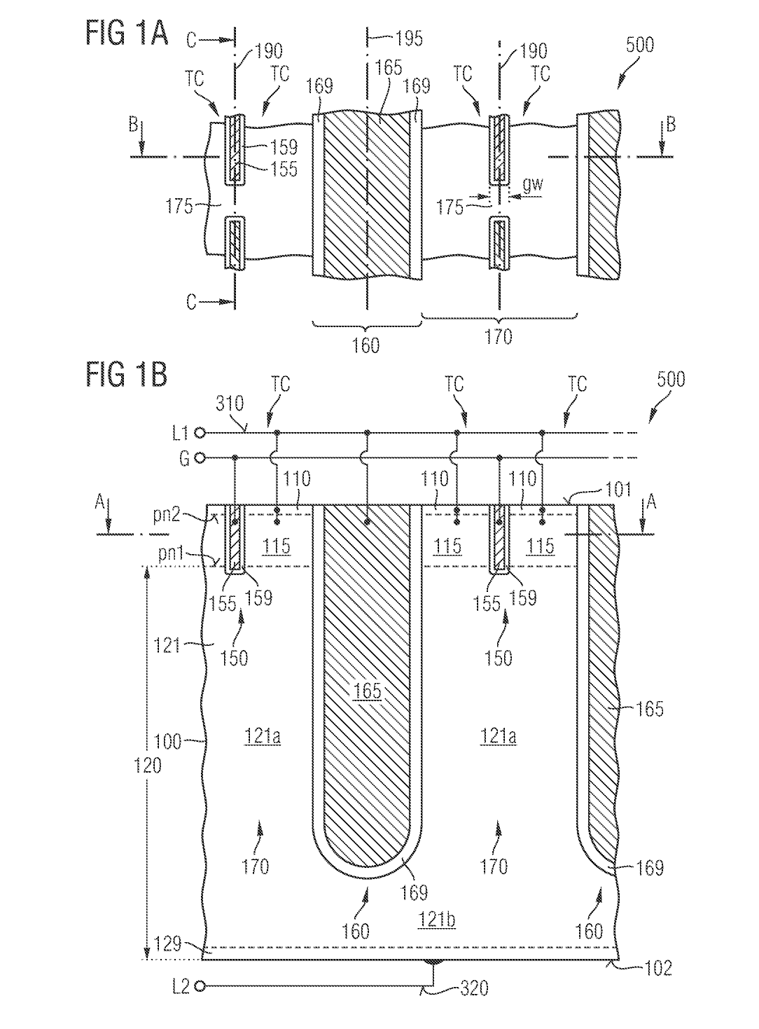

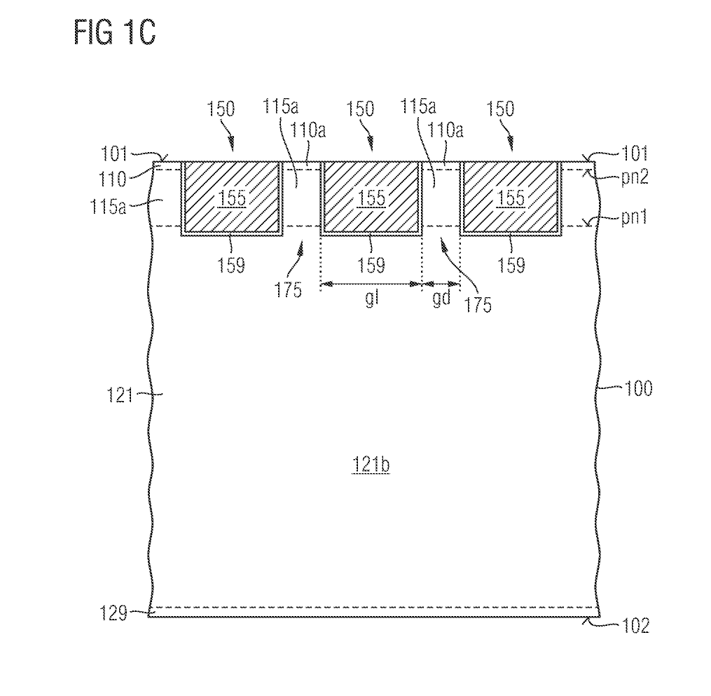

FIGS. 1A to 1C refer to a semiconductor device 500 including a plurality of identical transistor cells TC. The semiconductor device 500 may be or may include an IGFET, for example an MOSFET (metal oxide semiconductor FET) in the usual meaning including FETs with metal gates as well as FETs with non-metal gates. According to another embodiment, the semiconductor device 500 may be an IGBT (insulated gate bipolar transistor) or an MCD (MOS controlled diode).

The semiconductor device 500 is based on a semiconductor portion 100 from a single crystalline semiconductor material such as silicon (Si), silicon carbide (SiC), germanium (Ge), a silicon germanium crystal (SiGe), gallium nitride (GaN), gallium arsenide (GaAs) or any other A_{III}B_{V} semiconductor.

The semiconductor portion 100 has a first surface 101 which may be approximately planar or which may be defined by a plane spanned by coplanar surface sections as well as a planar second surface 102 parallel to the first surface 101. A distance between the first and second surfaces 101, 102 depends on a voltage blocking capability the semiconductor device 500 is specified for and may be at least 20 μm. According to other embodiments, the distance may be in the range of several hundred μm. A lateral surface, which is tilted to the first and second surfaces 101, 102 connects the first and second surfaces 101, 102.

In a plane perpendicular to the cross-sectional plane the semiconductor portion 100 may have a rectangular shape with an edge length of several millimeters. A normal to the first surface 101 defines a vertical direction and directions orthogonal to the vertical direction are horizontal directions.

The semiconductor portion 100 includes a drift structure 120 of a first conductivity type as well as a contact portion 129 between the drift structure 120 and the second surface 102. The drift structure 120 includes a drift zone 121, in which a dopant concentration may gradually or in steps increase or decrease with increasing distance to the first surface 101 at least in portions of its vertical extension. According to other embodiments, the dopant concentration in the drift zone 121 may be approximately uniform. A mean dopant concentration in the drift zone 121 may be between 1E14 cm⁻³ and 1E18 cm⁻³, for example, in a range from 5E15 cm⁻³ to 1E17 cm⁻³. For a silicon-based semiconductor portion 100 the mean dopant concentration in the drift zone 121 may be between 1E15 cm⁻³ and 1E17 cm⁻³, for example, in a range from 5E15 cm⁻³ to 5E16 cm⁻³.

The contact portion 129 may be a heavily doped base substrate or a heavily doped layer. Along the second surface 102 a dopant concentration in the contact portion 129 is sufficiently high to form an ohmic contact with a metal directly adjoining the second surface 102. In case the semiconductor portion 100 is based on silicon, in an n-conductive contact portion 129 the dopant concentration along the second surface 102 may be at least 1E18 cm⁻³, for example at least 5E19 cm⁻³. In a p-conductive contact portion 129, the dopant concentration may be at least 1E16 cm⁻³, for example at least 5E17 cm⁻³. For IGFETs and semiconductor diodes, the contact portion 129 has the same conductivity as the drift zone 121. For IGBTs the contact portions 129 may have the complementary second conductivity type.

The drift structure 120 may include further doped regions, e.g., a field stop layer or buffer zone between the drift zone 121 and the contact portion 129, barrier zones or counterdoped regions.

Field electrode structures 160 extend from the first surface 101 into the semiconductor portion 100. Portions of the field electrode structure 160 between the first surface 101 and buried end portions may have approximately vertical sidewalls or may slightly taper at an angle of, e.g., 89 degrees with respect to the first surface 101. The sidewalls may be straight or slightly bulgy.

The field electrode structures 160 may be stripe-shaped and may extend along parallel electrode lines 195, which may be equally spaced. According to an embodiment, the field electrode structures 160 may be dot-shaped and a plurality of field electrode structures 160 with the same horizontal cross-section area arranged along each electrode line 195.

Each field electrode structure 160 includes a conductive field electrode 165 and a field dielectric 169 surrounding the field electrode 165, respectively. The field electrode 165 includes or consists of a heavily doped silicon layer and/or a metal-containing layer. The field dielectric 169 separates the field electrode 165 from the surrounding semiconductor material of the semiconductor portion 100 and may include or consist of a thermally grown silicon oxide layer, a deposited silicon oxide layer, e.g. a silicon oxide based on TEOS (tetraethyl orthosilicate), or both.

A vertical extension of the field electrode structure 160 is smaller than a distance between the first surface 101 and the contact portion 129 such that a contiguous drift zone section 121b is formed between the field electrode structures 160 and the contact portion 129 and columnar drift zone sections 121a are formed between neighboring field electrode structures 160. The vertical extension of the field electrode structures 160 may be in a range from 1 μm to 50 μm, for example in a range from 2 μm to 20 μm. A first horizontal extension of the field electrode structures 160 orthogonal to the electrode lines 195 may be in a range from 0.1 μm to 20 μm, for example in a range from 0.2 μm to 5 μm.

For spicular or needle-shaped field electrodes 165, a second horizontal extension of the field electrode 165 orthogonal to the first horizontal extension and parallel to the electrode lines 195 may be at most three times or at most twice as large as the first horizontal extension, wherein the cross-sectional areas of the field electrodes 165 and the field electrode structures 160 may be rectangles, or regular or distorted polygons with or without rounded and/or beveled corners, ellipses or ovals, respectively.

According to an embodiment, the first and second horizontal extensions are approximately equal and the cross-sectional areas of the field electrodes 165 and the field electrode structures 160 are circles or regular polygons with or without rounded or beveled corners, such as octagons, hexagons or squares.

The field electrode structures 160 allow high dopant concentrations in the drift zone 121 without adversely affecting the blocking capabilities of the semiconductor device 500. Needle-shaped field electrodes 165 increase the available cross-sectional area for the drift zone 121 and therefore reduce the on-state resistance RDSon compared to stripe-shaped field electrodes.

Semiconducting portions of the transistor cells TC are formed in mesa sections 170 of the semiconductor portion 100, wherein the mesa sections 170 may be stripes extending parallel to stripe-shaped field electrode structures 160 or may form a grid embedding dot-shaped field electrode structures 160. The mesa sections 170 protrude from a contiguous section of the semiconductor portion 100 between the field electrode structures 160 and the second surface 102. A horizontal mean width of the mesa sections 170 may be in a range from 0.2 μm to 10 μm, for example in a range from 0.3 μm to 1 μm.

Each mesa section 170 includes a body zone 115 of the second conductivity type. The body zones 115 form first pn junctions pn1 with the drift structure 120, e.g., the first drift zone sections 121a, and second pn junctions pn2 with source zones 110 formed between the body zones 115 and the first surface 101. For dot-shaped field electrode structures 160, the body zones 115 completely surround the field electrode structures 160 in a horizontal plane.

The source zones 110 may be wells extending from the first surface 101 into the semiconductor portion 100, for example into the body zones 115. In case of a dot-shaped field electrode structure 160, one source zone 110 may surround the field electrode structure 160 in a horizontal plane. The source zone(s) 110 may directly adjoin the field electrode structure 160 or may be spaced from the field electrode structure 160.

The source zones 110 as well as the body zones 115 are electrically connected to a first load electrode 310. The first load electrode 310 may be electrically coupled or connected to a first load terminal L1, for example the source terminal in case the semiconductor device 500 is an IGFET, an emitter terminal in case the semiconductor device 500 is an IGBT or an anode terminal in case the semiconductor device 500 is a semiconductor diode.

A second load electrode 320, which directly adjoins the second surface 102 and the contact portion 129, may form or may be electrically connected to a second load terminal L2, which may be the drain terminal in case the semiconductor device 500 is an IGFET, a collector terminal in case the semiconductor device 500 is an IGBT or a cathode terminal in case the semiconductor device 500 is a semiconductor diode.

The field electrodes 165 may be electrically connected to the first load electrode 310, to another terminal of the semiconductor device 500, to an output of an internal or external driver circuit, or may float. The field electrodes 165 may also be divided in different subelectrodes which may be insulated from each other and which may be coupled to identical or different potentials.

Gate fines 150 extend from the first surface 101 into the semiconductor portion 100. The gate fines 150 are arranged along element lines 190, wherein all element lines 190 may be separated from each other. For example, all element lines 190 may be parallel to each other or may form closed loops, e.g., circles. According to another embodiment, element lines 190 of a first group intersect element lines 190 of a second group. Longitudinal axes of the gate fins 150 are parallel to the element lines 190 or may coincide with the element lines 190. Column sections 175 of the semiconductor portion 100 separate neighboring gate fins 150 from each other along the element lines 190.

The element lines 190 run parallel to the electrode lines 195 along which stripe-shaped field electrode structures 160 extend or along which dot-shaped field electrode structures 160 are arranged.

Each gate fin 150 includes a portion of a conductive gate electrode 155, which includes or consists of a heavily doped polycrystalline silicon layer and/or a metal-containing layer. The gate electrode 155 is completely insulated against the semiconductor portion 100, wherein a gate dielectric 151 separates the gate electrode 155 at least from the body zones 115. The gate dielectric 151 capacitively couples the gate electrode 155 to channel portions of the body zones 115. The gate dielectric 151 may include or consist of a semiconductor oxide, for example thermally grown or deposited silicon oxide, semiconductor nitride, for example deposited or thermally grown silicon nitride, a semiconductor oxynitride, for example silicon oxynitride, or a combination thereof. The gate electrode 155 is electrically connected or coupled to a gate terminal G of the semiconductor device 500.

A vertical extension of the gate fins 150 is smaller than a vertical extension of the field electrode structures 160. The vertical extension of the gate structures 150 may be in a range from 100 nm to 5000 nm, for example in a range from 300 nm to 1000 nm. A gate length gl of the gate fins 150 along the element lines 190 may be at least 200 nm, e.g., at least 250 nm. A ratio of the gate length g1 to a center-to-center distance (pitch) of the transistor cells TC may be at most 95%, e.g., at most 90%. A gate width gw of the gate fins 150 orthogonal to the element lines 190 may be at least 150 nm, for example at least 200 nm.

The column sections 175 define gate gaps and may include source column portions 110a of the source zones 110 as well as body column portions 115a of the body zones 115. A width gd of the column sections 175 along the element lines 190 may be in a range from 150 nm to 400 nm, for example in a range from 200 nm to 350 nm such that the body column sections 115a are completely depleted at a gate-to-first-load-terminal voltage VGL1=0V and a DIBL (drain induced barrier lowering) is reduced.

In the illustrated embodiments and for the following description, the body zones 115 are p-type, whereas the source zones 110 and the drift zone 121 are n-type. Similar considerations as outlined below apply also to embodiments with n-type body zones 115 as well as p-type source zones 110 and a p-type drift zone 121.

When a voltage applied to the gate electrode 150 exceeds a preset threshold voltage, electrons accumulate in the channel portions of the body zones 115 directly adjoining the gate dielectric 159 and form inversion channels by-passing the second pn junctions pn2 for electrons in a forward biased state of the semiconductor device 500 with a positive voltage applied between the drift structure 120 and the source zones 110. As a result, a load current flows between the first and second load terminals L1, L2 in vertical direction through the semiconductor device 500.

A parasitic gate-to-drain capacity Cgd is proportional to an overlap area between the gate electrode 155 and the drift structure 120. Compared to contiguous gate electrodes 155, the gate gaps defined by the column sections 175 do not contribute to the gate-to-drain capacity Cgd. The gate gaps may significantly reduce the overlap area between the gate electrode 155 and the drift structure 120 and reduce Cgd as well as the small-signal reverse transfer characteristics Crss.

The reduction in channel width along the longitudinal sides of the gate fins 150 may be at least partly compensated by additional channel width along the end faces of the gate fins 150 along the column section 175. Depending on the horizontal cross-sectional shape of the gate fins 150 and the uniformity of the gate dielectric 159, a minimum gate width gw in the range of the gate gap width gd may suffice to compensate for or even overcompensate the loss of channel width along the longitudinal direction.

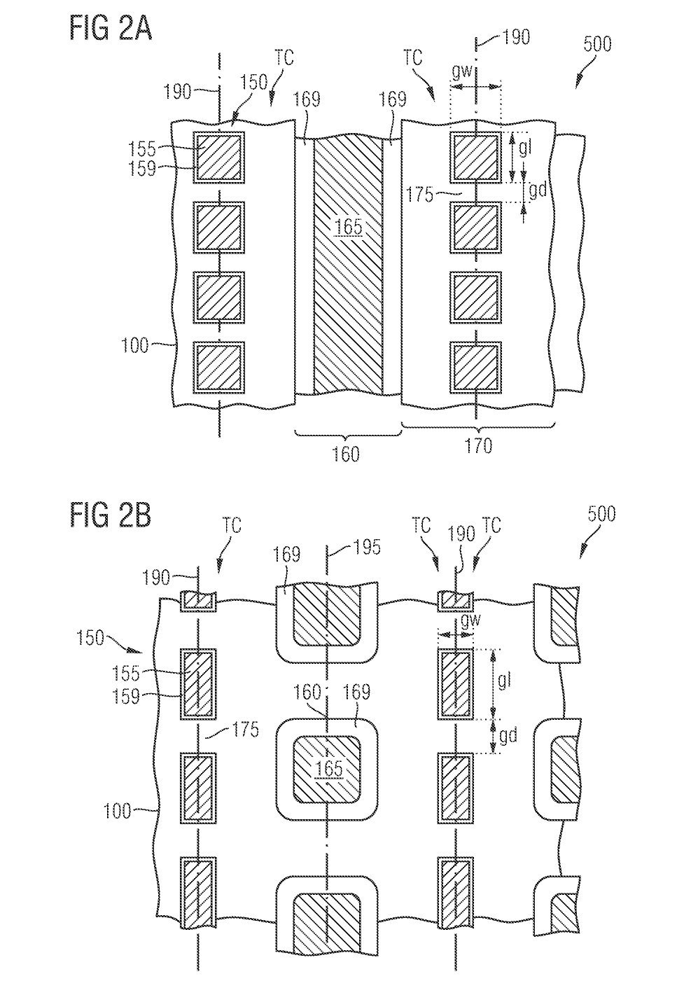

FIG. 2A refers to a semiconductor device 500 with stripe-shaped field electrode structures 160 as well as gate fins 150 arranged along parallel element lines 190. The element lines 190 may be equidistant to each other at least in a transistor cell field in which controllable active transistor cells TC are formed, through which a load current flows in an on-state of the semiconductor device 500. Compared to continuous gate electrodes, the column sections 175 between the gate fins 150 reduce overall gate-to-drain capacity Cgd. Additional channel width at the end faces of the gate fins 150 on opposite sides of the intermediate columns sections 175 at least partly compensate for the loss of channel width along the longitudinal sides of the gate fins 150.

In FIG. 2B the semiconductor device 500 combines gate fins 150 with spicular field electrodes 165 arranged along electrode lines 195, which are parallel to the element lines 190, for further reducing parasitic capacitances.

In conventional layouts with a continuous gate electrode surrounding dot-shaped field electrode structures 160, the continuous gate electrode forms a continuous grid with nodes where orthogonal gate electrode portions cross.

In layouts with a continuous grid-shaped gate electrode without variation of a width of the continuous gate electrode, the crossing portions of the gate electrode 155 form sharp corners. In and next to the sharp corners, electric fields of the two orthogonal gate electrode portions overlap and locally reduce the threshold voltage in a portion of the concerned transistor cell TC.

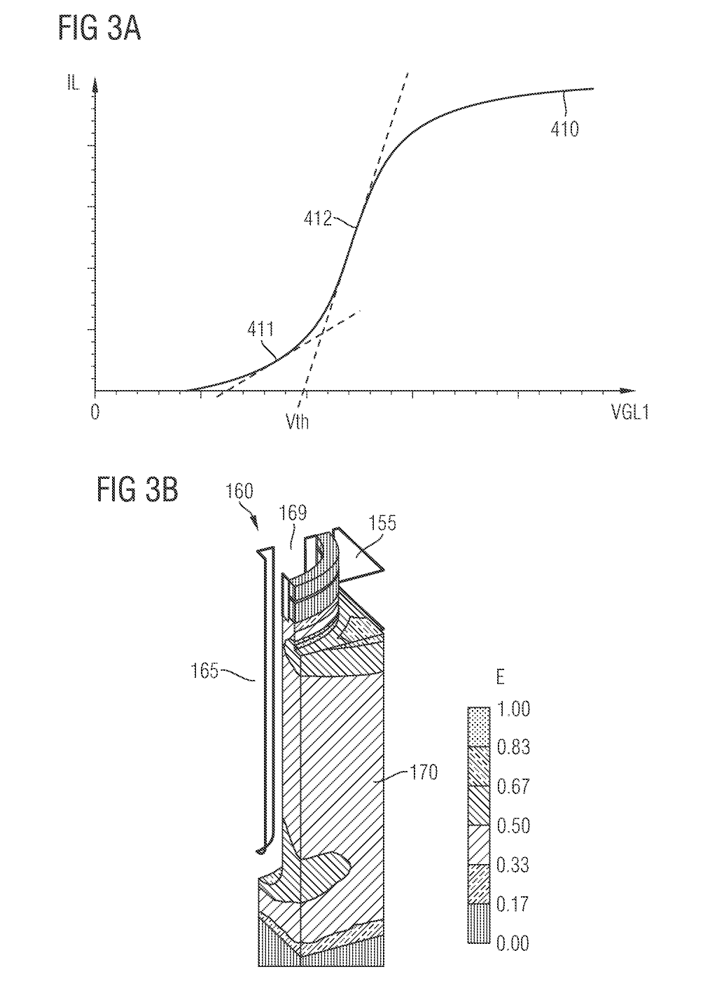

FIG. 3A is a diagram plotting a load current IL against a gate-to-first-load-electrode-voltage VGL1, e.g., the gate-to-source voltage VGS in case of IGFETs, and shows the transfer characteristic 410 of a conventional semiconductor device with crossing gate electrodes. A first part 411 of the transfer characteristic 410 originates from the transistor cell portions close to the corners, which are conductive yet at low voltages, and a second part 412 originates from the transistor cell portions distant to the corners, which conduct a load current only above the target threshold voltage Vth.

For ensuring a defined target threshold voltage Vth of, e.g., 10V, the threshold voltage in the complete transistor cell TC is shifted to higher values. As a side effect, a local threshold voltage in portions distant to the corners is shifted to above the target threshold voltage and, as a further consequence, on-resistance RDSon is increased.

Rounded corners reduce the effect of overlapping electric fields but locally widen the gate electrodes at and next to the nodes of the grid. The width of the gate electrodes is typically defined by the width of a gate trench, which in the course of manufacturing is etched into the semiconductor portion and which is later filled with the gate electrode. In typical etch regimes, for a given etch time a depth of an etched trench depends on a width of the etched trench. Locally widening the gate electrode at the nodes therefore typically results in gate electrodes with locally increased vertical extension at and around the nodes.

Further in grid-shaped gate electrodes high electric field strengths occur in the mesa sections along the bottom of the gate electrode along the edge opposite to the field electrode structure as illustrated in FIG. 3B, wherein the electric field strength E increases with increasing distance between the concerned edge and the first surface 101. This effect is pronounced along a line connecting two field electrode structures on opposite sides of an intermediate node, where, for rounded corners, the gate electrode has its maximum vertical extension due to the above described process characteristics. As a consequence, in case of rounded meshes, the increased vertical extension of the gate electrodes at the nodes results in high electric field strengths at the bottom of the gate electrodes at the nodes and severely affects reliability of the gate dielectric.

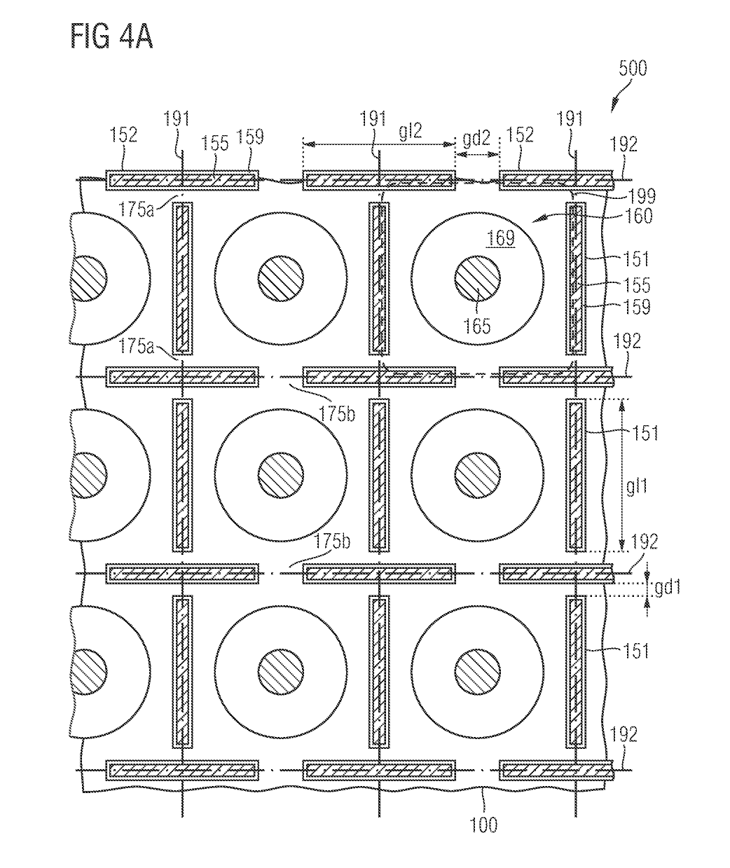

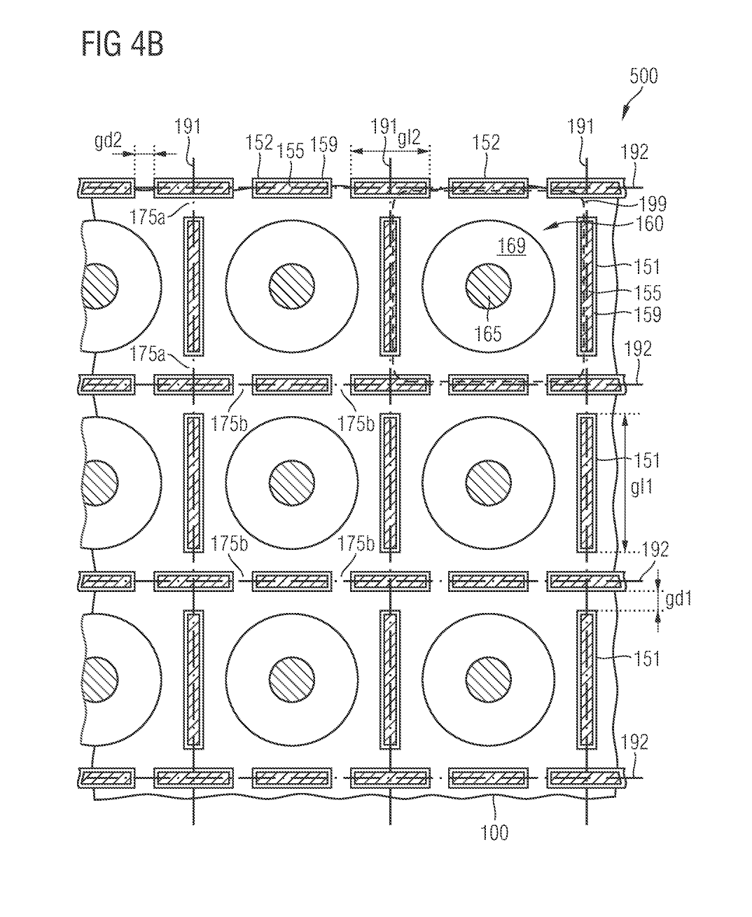

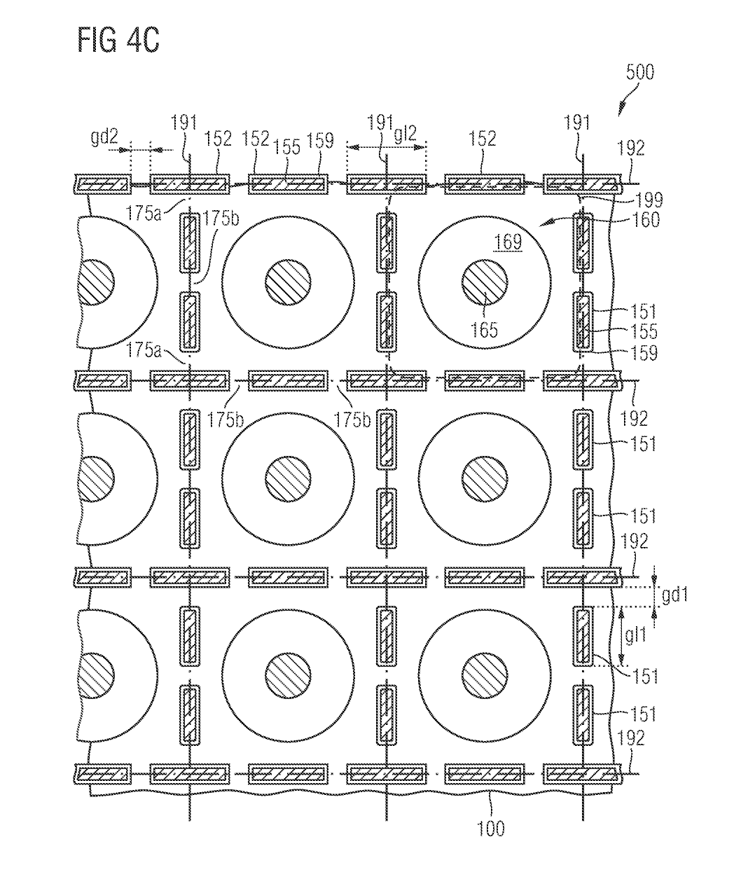

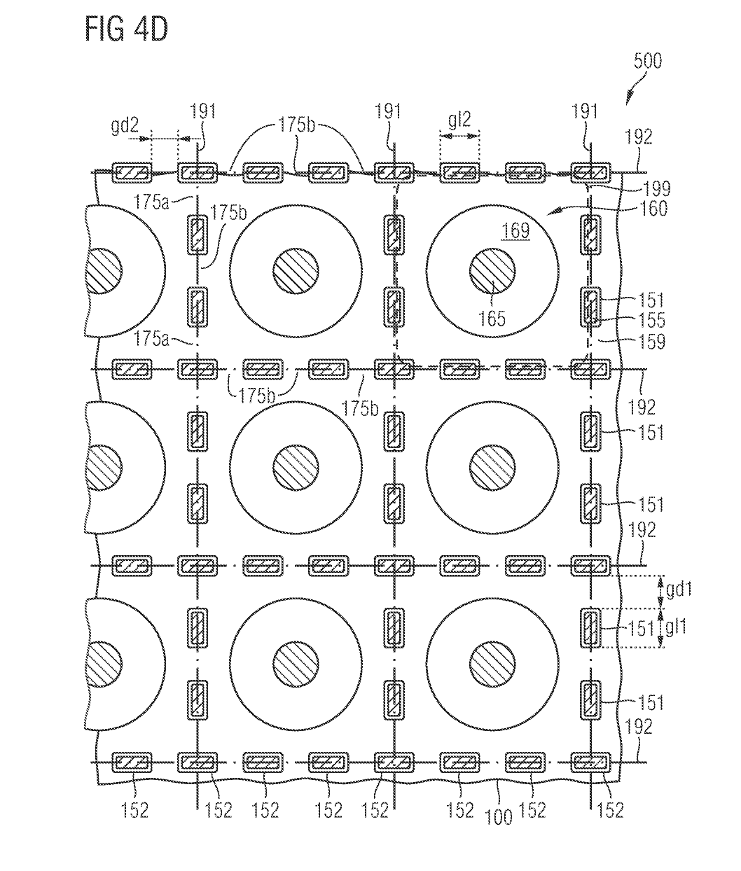

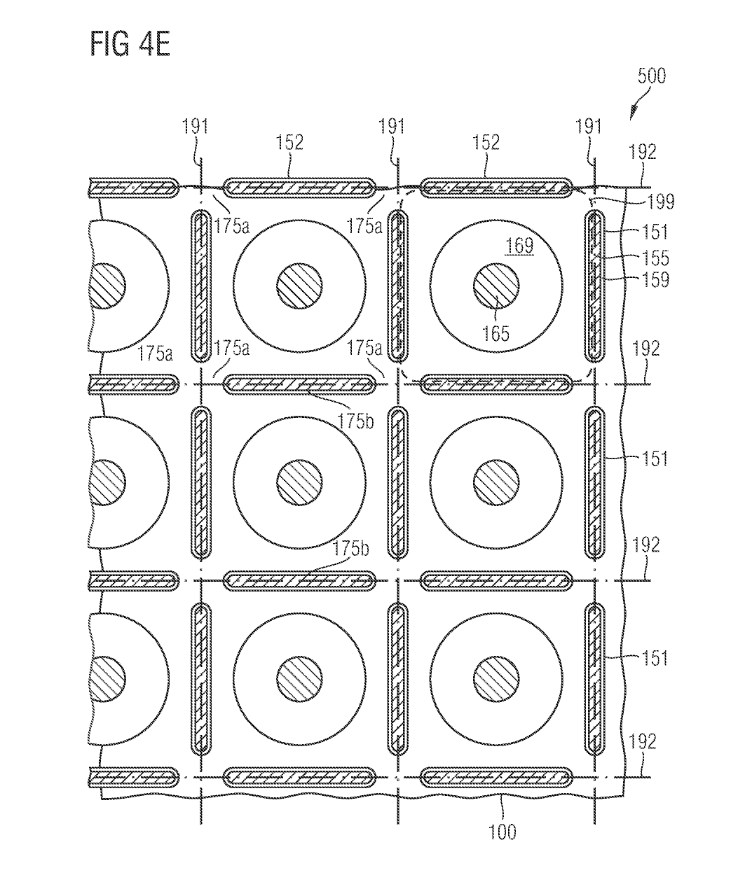

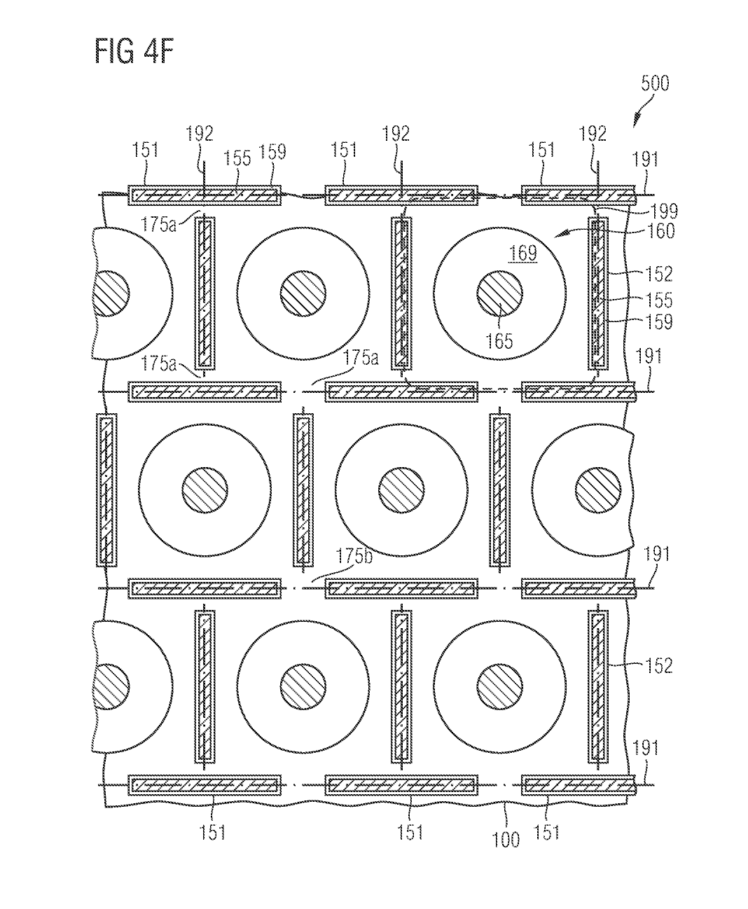

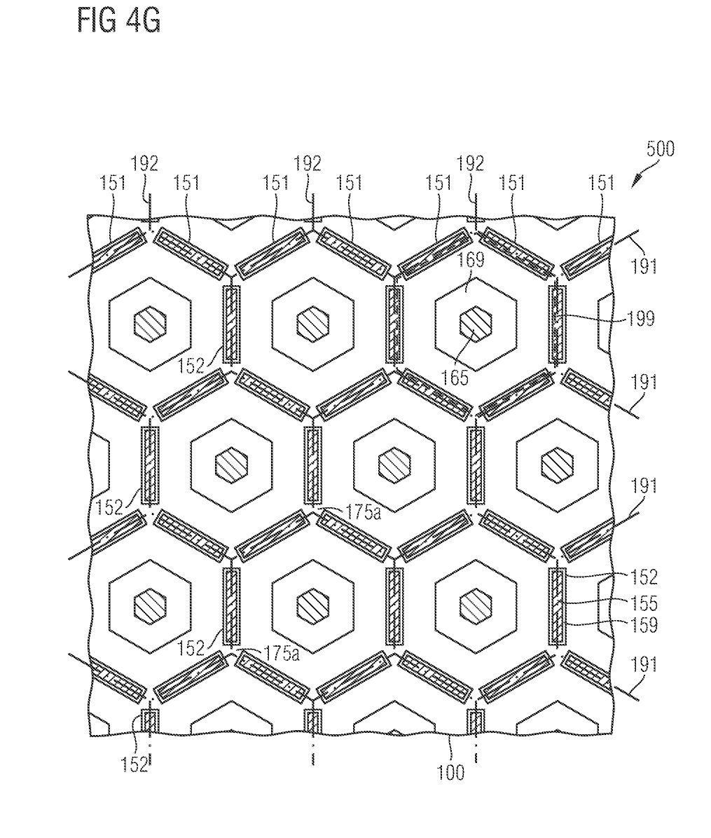

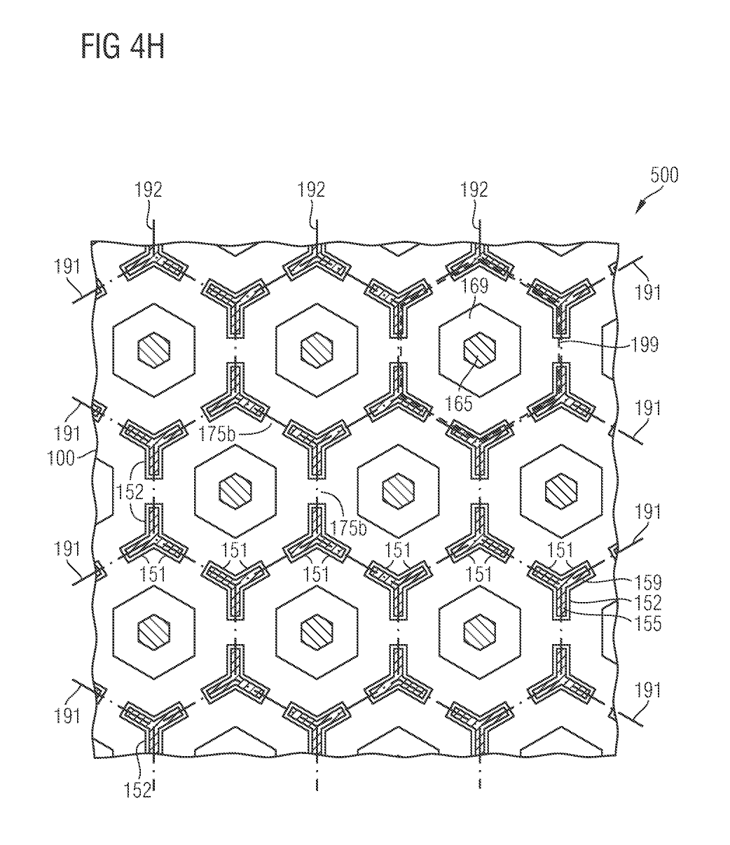

Instead, FIGS. 4A to 4F refer to semiconductor devices 500 including first gate fins 151 formed along first element lines 191 and second gate fins 152 formed along second element lines 192 that intersect or are tangent to the first element lines 191, for example, at an angle of 90 or 120 degree. The first element lines 191 are separated from each other and the second element lines 192 are separated from each other. The first and second element lines 191, 192 may form a grid with the field electrode structures 160 formed in the center of the meshes 199 of the grid.

At least the first element lines 191 may be continuous lines, e.g., straight lines, zig-zag lines or curved lines and run side-by side along the same direction. Neighboring first element lines 191 may be symmetric to each other with respect to an intermediate symmetry axis, e.g., may be parallel to each other.

The second element lines 192 may be continuous lines, e.g., continuous straight, zig-zag or curved lines or may be discontinuous lines with sections of the same second element line 192 tangent to two neighboring first element lines 191, respectively. The second element lines 192 may intersect or may be tangent to zig-zag first element lines 191 at the bends of the first element lines 191. Meshes of the grid may be rectangles, e.g., squares or other regular polygons such as hexagons or octagons.

First column sections 175a separate first and second gate fins 151, 152 from each other such that the first and second gate fins 151, 152 do not cross. The column sections 175a in the semiconductor devices 500 of FIGS. 4A to 4F avoid a local threshold shift without widening the gate electrodes, hence, without adversely affecting the reliability of the gate dielectric 159.

In addition, avoiding portions of the gate electrode 155 with increased vertical extension also avoids an additional areal overlap between the gate electrode 155 and the drift structure 120 and keeps a parasitic gate-to-drain capacity Cgd low.

In FIG. 4A first column sections 175a separate first fins 151, which longitudinal axes are oriented along parallel, straight first element lines 191, from second fins 152, which longitudinal axes are oriented along parallel, straight second element lines 192 orthogonal to the first element lines 191. The first column sections 175a avoid a local lowering or the gate threshold voltage Vth in the corners of the meshes 199 without local modification of the width of the gate electrode 155 and without adversely affecting the reliability of the gate dielectric 159.

In addition to the first column sections 175a, the semiconductor device 500 may include second columns sections 175b separating neighboring second gate fins 152 or neighboring first gate fins 151 from each other. By reducing the effective overlap area between the gate electrode 155 and the drift structure 120, the first and second column sections 175a, 175b further reduce the gate-to-drain capacity Cgd.

As illustrated in FIG. 4A, the gate length g11 of the first gate fins 151 may be approximately equal to the gate length gl2 of the second gate fins 152. According to another embodiment a width gd1 of the first column sections 175a may be approximately equal to a width gd2 of the second column sections 175b. Meshes of a grid formed by the first and second element lines 191, 192 may form squares.

While in the semiconductor device 500 of FIG. 4A each mesh 199 includes, in total, six first and second column sections 175a, 175b, the semiconductor device 500 illustrated in FIG. 4B includes four second column sections 175b in addition to the four first column sections 175a. The second column sections 175b may be formed exclusively between first gate fins 151, exclusively between second gate fins 152 or both between first gate fins 151 and second gate fins 152. The widths of the second columns sections 175b may be equal or may vary. Channels formed along the end faces of the gate fins 151, 152 may at least partly compensate a loss of channel width resulting from the gate gaps along the long sides of the first and second gate fins 151, 152.

FIG. 4C refers to a semiconductor device 500 with second column sections 175b both between first gate fins 151 and between second gate fins 152. A width gd1 of the first column sections 175a may be approximately equal to a width gd2 of the second column sections 175b.

The semiconductor device 500 of FIG. 4D includes meshes with eight second columns sections 175b per mesh. According to other embodiments, the first and second gate fins 151, 152 may be dot-shaped such that a total channel width per transistor cell is large while at the same time a gate-to-drain overlap is low compared to a continuous, grid-like gate electrode.

In FIG. 4E first column sections 175a include the crossing area of the first and second element lines 191, 192 and separate also neighboring first gate fins 151 and neighboring second gate fins 152 from each other. In addition to the first column sections 175a, the semiconductor device 500 may or may not include second column sections separating only first gate fins 151 or only second gate fins 152 from each other.

FIGS. 4A to 4E show layouts with the field electrode structures 160 arranged in a matrix with rows and lines.

FIG. 4F refers to a layout with each odd line of meshes shifted with respect to the even lines of meshes by half a center-to-center distance between neighboring field effect structures 160 along the lines of meshes. The first element lines 191 are continuous straight lines, whereas the second element lines 192 are discontinuous lines with sections of each second element line 192 aligned to each other in the longitudinal direction and connecting two neighboring first element lines 191, respectively. First column sections 175a include the crossing areas of the first and second element lines 191, 192. Each first column section 175a separates two neighboring first gate fins 151 and one second gate fin 152 from each other.

In FIG. 4G the first element lines 191 are continuous zig-zag lines and the second element lines 192 are discontinuous straight lines tangent to the first element lines 191 at the bends of the first element lines 191. Meshes of the resulting grid of first and second element lines 191, 192 may be regular hexagons. Horizontal cross-sections of the field electrode structures 160 may be hexagons, hexagons with rounded corners, or circles. First column sections 175a include the crossing areas of the first and second element lines 191, 192, wherein each first column section 175a separates two neighboring first gate fins 151 and one second gate fin 152 from each other.

The semiconductor device 500 of FIG. 4H differs from the one in FIG. 4G by second column sections 175b outside of the crossing areas of the first and second element lines 191, 192, wherein each second column section 175b separates two neighboring first gate fins 151 or two neighboring second gate fins 152 from each other. Each second gate fin 152 may be structurally connected to two first gate fins 151. According to another embodiment, the semiconductor device 500 may include both the first column sections 175a of FIG. 4G and the second column sections 175b of FIG. 4H.

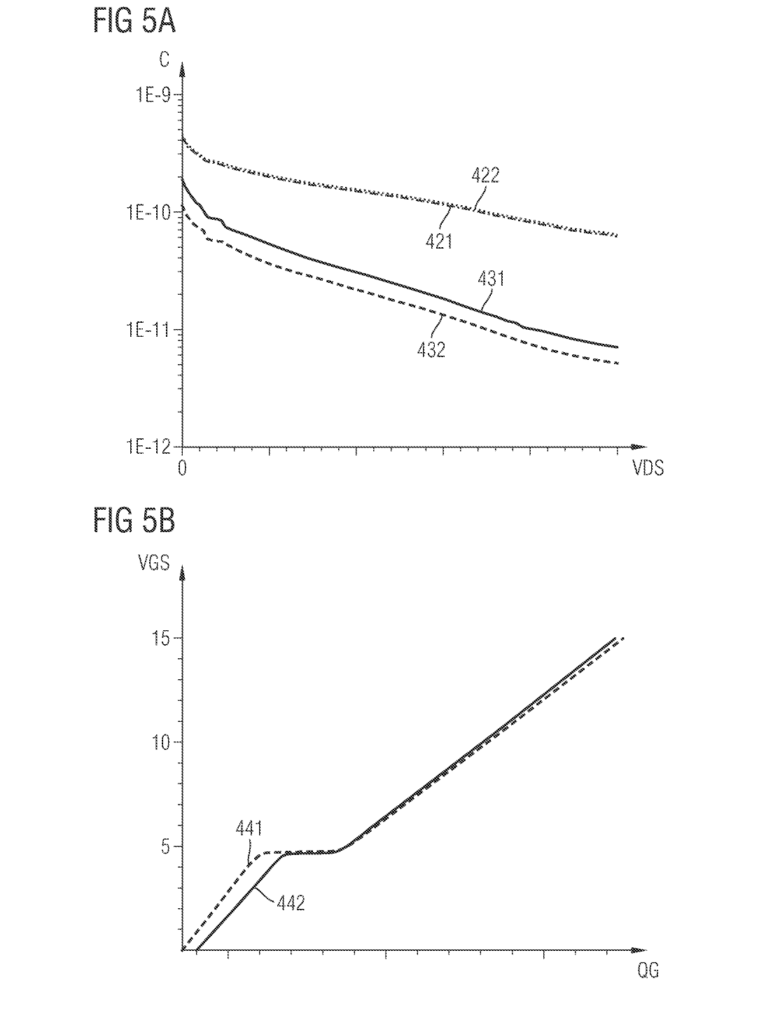

FIG. 5A is a schematic diagram showing small-signal reverse transfer characteristics Crss 432, 431 and small-signal output capacitance Coss 422, 421 of semiconductor devices with and without gate gaps as a function of the drain-to-source voltage VDS, wherein the semiconductor devices are identical in the rest. While the gate gaps hardly affect Coss, Crss 432 of the semiconductor device with gate gaps is significantly reduced compared to Crss 431 of the semiconductor device without gate gaps.

FIG. 5B is a schematic diagram showing the gate voltage 442, 441 as a function of the gate charge for semiconductor devices with and without gate gaps and identical in the rest. The gate gaps significantly narrow the Miller-Plateau.

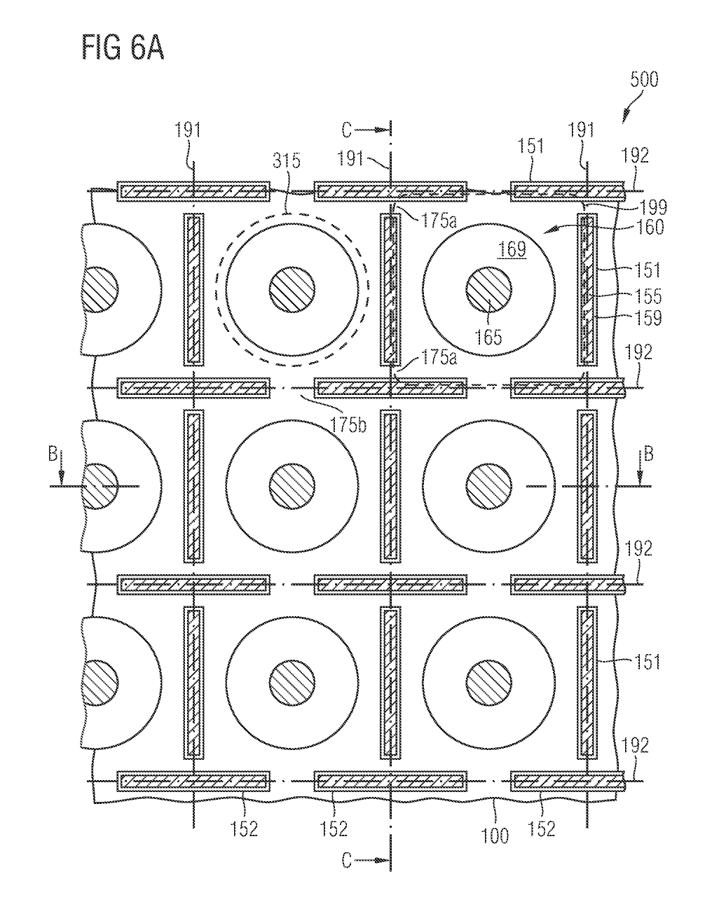

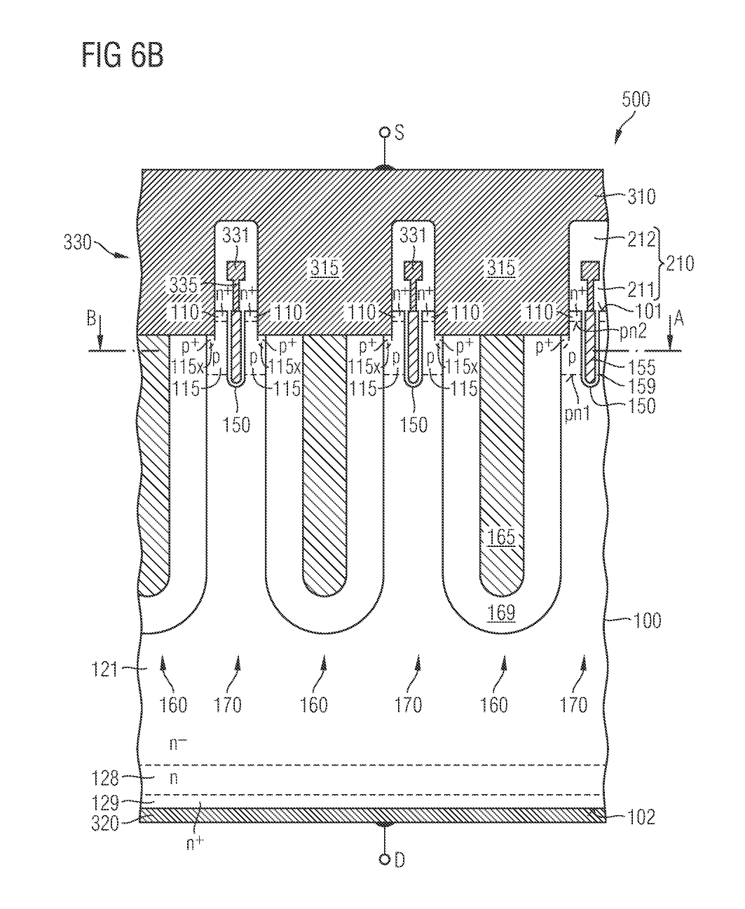

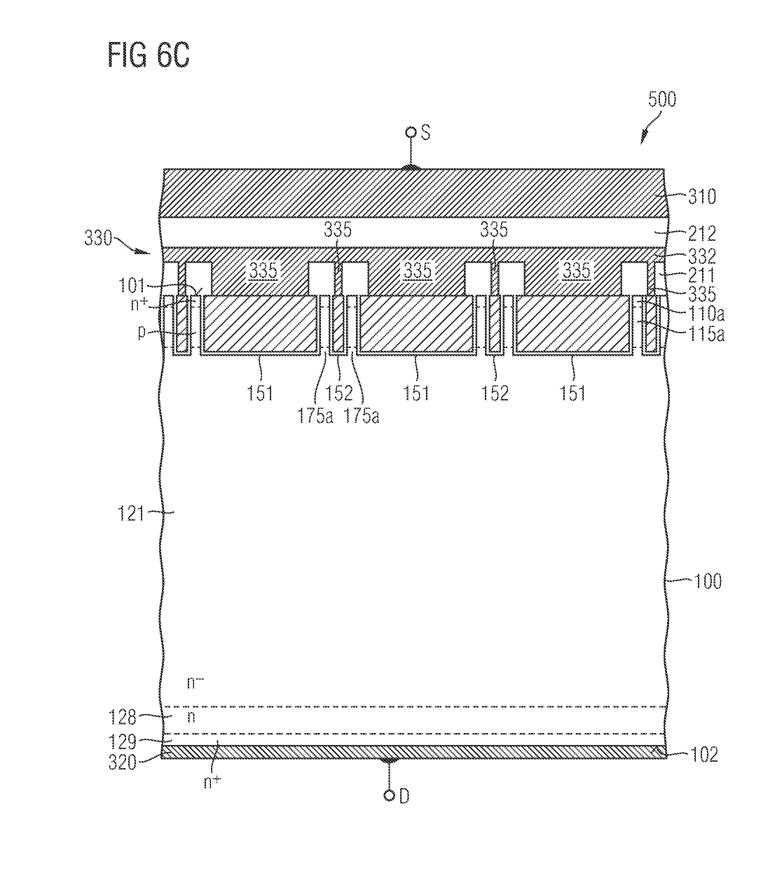

The semiconductor device 500 in FIGS. 6A to 6C is an IGFET based on a semiconductor portion 100 including transistor cells TC with field electrode structures 160 and first and second gate fins 151, 152 as described in detail with respect to the previous Figures, wherein the first load terminal is a source terminal S and the second load terminal is a drain terminal D.

In a distance to the first surface 101 and outside the semiconductor portion 100, a gate wiring 330 includes continuous first wiring portions 331 parallel to and in the vertical projection of the first element lines 191 as well as continuous second wiring portions 332 parallel to and in the vertical projection of the second element lines 192. The gate wiring 330 may consist of or include a metal layer, e.g., a layer from Al or W, and may include further adhesion and/or diffusion barrier layers, e.g., layers containing Ti or Ta. The gate wiring 330 is electrically connected or coupled to the gate terminal.

A pre-metal dielectric 211 separates the gate wiring 330 from the mesa sections 170. The pre-metal dielectric 211 may include one or more dielectric layers from silicon oxide, silicon nitride, silicon oxynitride, doped or undoped silicate glass, for example BSG (boron silicate glass), PSG (phosphorus silicate glass) or BPSG (boron phosphorus silicate glass), by way of example.

Gate contacts 335 extend through openings in the pre-metal dielectric 211 and electrically connect the gate wiring 330 with the gate electrodes 155 in the gate fins 150. The gate contacts 335 may consist of the same materials or material combinations as the gate electrode 155 or may have a composition different from that of the gate electrodes 155. For example, the gate contacts 335 may consist of or include a metal layer, e.g., a tungsten portion and, between the tungsten portion and the pre-metal dielectric 211, further adhesion and/or diffusion barrier layers, e.g., layers containing Ti or Ta.

The first load electrode 310 may be a metal plate in a distance to the gate wiring 330, wherein an inter-metal dielectric 212 separates the first load electrode 310 from the gate wiring 330. The inter-metal dielectric 212 may include one or more dielectric layers from silicon oxide, silicon nitride, silicon oxynitride, doped or undoped silicate glass, for example BSG, PSG or BPSG.

Load contact structures 315 extend through openings in an interlayer dielectric 210 including the pre-metal dielectric 211 and the inter-metal dielectric 212 and electrically connect the first load electrode 310 with the source zones 110, the body zones 115, and the field electrodes 165. The load contact structures 315 may include one or more conductive metal containing layers based on, e.g., Ti or Ta and a metal fill portion, e.g., based on W.

Each of the first and second load electrodes 310, 320 may consist of or contain, as main constituent(s), aluminum (Al), copper (Cu), or alloys of aluminum or copper, for example AlSi, AlCu or AlSiCu. According to other embodiments, at least one of the first and second load electrodes 310, 320 may contain, as main constituent(s), nickel (Ni), tin (Sn), titanium (Ti), tungsten (W), tantalum (Ta), vanadium (V), silver (Ag), gold (Au), platinum (Pt), and/or palladium (Pd). For example, at least one of the first and second load electrodes 310, 320 may include two or more sub-layers, wherein each sub-layer contains one or more of Ni, Sn, Ti, V, Ag, Au, Pt, W, and Pd as main constituent(s), e.g., a silicide, a nitride and/or an alloy.

The drift structure 120 may include further doped zones, for example a field stop layer 128 that separates the drift zone 121 from the contact portion 129, wherein a mean dopant concentration in the field stop layer 128 may be at least five times as high as a mean impurity concentration in the drift zone 121 and at most one-fifth of a maximum dopant concentration in the contact portion 129.

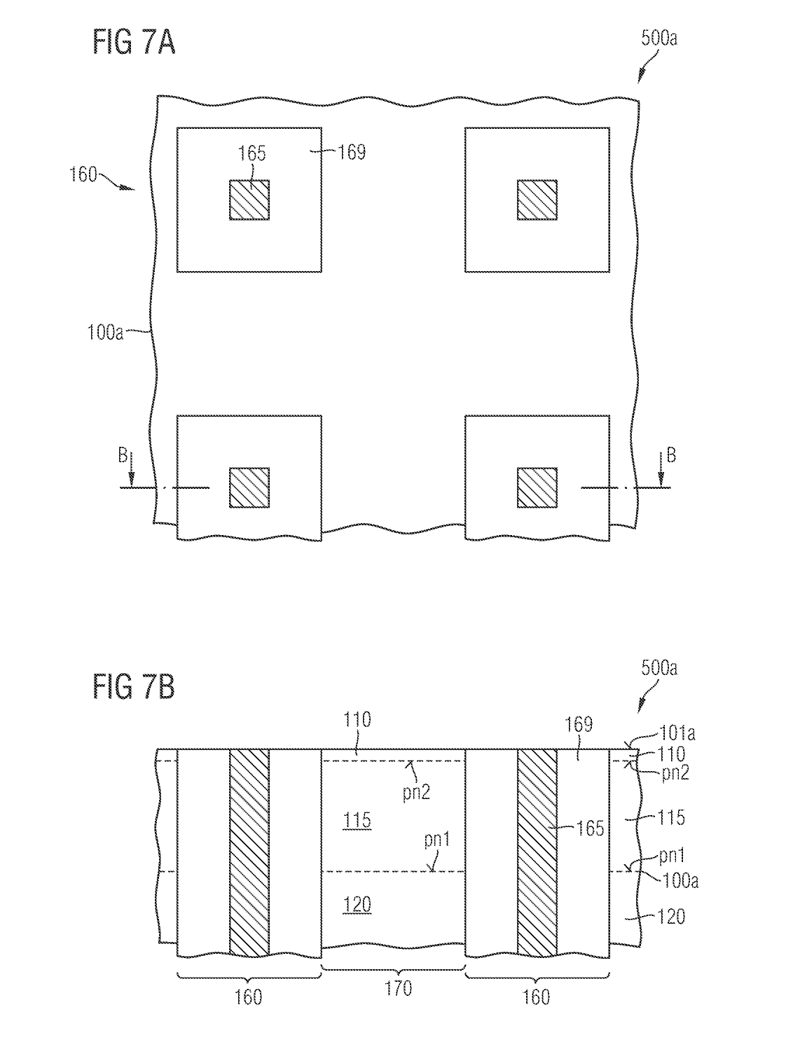

FIGS. 7A to 11B refer to a method of manufacturing semiconductor devices with gate fins 151, 152 electrically connected through a gate wiring 330 as illustrated in FIGS. 5A to 5C.

FIGS. 7A and 7B show a semiconductor substrate 500a that consists of or includes a semiconductor layer 100a of a crystalline semiconductor material. The semiconductor substrate 500a may be a semiconductor wafer from which a plurality of identical semiconductor dies is obtained. The single-crystalline semiconductor material of the semiconductor layer 100a may be Si, SiC, Ge, SiGe, GaN, GaAs or any other A_{III}B_{V} semiconductor. The semiconductor layer 100a may be intrinsic or lightly doped. According to an embodiment, the semiconductor layer 100a is lightly n-doped. For example, the semiconductor layer 100a contains phosphorus (P) and/or arsenic (As) atoms. A planar process surface 101a of the semiconductor layer 100a is exposed at a front side.

Field electrode structures 160 extend from the process surface 101a into the semiconductor layer 100a. Each field electrode structure 160 includes a conductive stripe-shaped or spicular field electrode 165 as well as a field dielectric 169 surrounding the field electrode 165. The field electrodes 165 include or consist of a heavily doped polycrystalline silicon layer and/or a metal containing layer. The field dielectrics 169 separate the field electrodes 165 from the surrounding semiconductor material of the semiconductor layer 100a and may include or consist of a thermally grown silicon oxide layer, a deposited silicon oxide layer, e.g., a silicon oxide based on TEOS or both.

The cross-sectional areas of the field electrodes 165 and the field electrode structures 160 may be stripes with a first horizontal extension exceeding at least ten times a second horizontal extension perpendicular to the first horizontal extension. According to the illustrated embodiment, the cross-sectional areas of the field electrodes 165 and the field electrode structures 160 are dot-shaped with a first horizontal extension exceeding the second horizontal extension at most three times. For example, the cross-sectional areas may be regular or distorted polygons such as rectangles, hexagons or octagons with or without rounded and/or beveled corners, respectively. According to an embodiment, the first and second horizontal extensions are approximately equal and the cross-sectional areas of the field electrodes 165 and the field electrode structures 160 are regular polygons such as octagons, hexagons or squares with or without rounded and/or beveled corners, respectively.

According to other embodiments, the cross-sectional areas of the field electrodes 165 and the field electrode structures 160 may be ellipses or ovals, or, in case the first and second horizontal extensions are equal, circles.

A minimum horizontal extension of the field electrodes 165 may be in a range from 0.1 μm to 20 μm, for example in a range from 0.2 μm to 5 μm. A vertical extension of the field electrode structures 160 and may be in a range from 1 μm to 50 μm, for example in a range from 2 μm to 20 μm.

Buried bottom sections of the field electrode structures 160 may be approximately horizontal or may be rounded. Vertical sidewall sections of the field electrode structures 160 between the process surface 101a and the bottom section may be strictly vertical, may slightly taper and/or may be bulgy.

Portions of the semiconductor layer 100a between neighboring field electrode structures 160 form mesa sections 170. The mesa sections 170 may be stripe-shaped or, as illustrated, may form a grid embedding spicular field electrode structures 160. A minimum mesa width may be in a range from 300 nm to 1 μm, for example in a range from 400 nm to 800 nm.

The mesa sections 170 may include body zones 115 forming first pn junctions pn1 with a drift structure 120 and second pn junctions pn2 with source zones 110 formed between the process surface 101a and the body zones 115.

A pre-metal dielectric layer is deposited on the process surface 101. A lithography process forms isolated gate openings 211a in the pre-metal dielectric layer along parallel first element lines 191 and along parallel second element lines 192 orthogonal to the first element lines 191. An etch process, e.g., an RIE (reactive ion etch) uses the patterned pre-metal dielectric layer as etch mask and forms first and second gate trenches 151a, 152a in the semiconductor layer 100a in the vertical projection of the gate openings 211a, wherein the first gate trenches 151a are formed along the first element lines 191 and the second gate trenches 152a are formed along the second element lines 192.

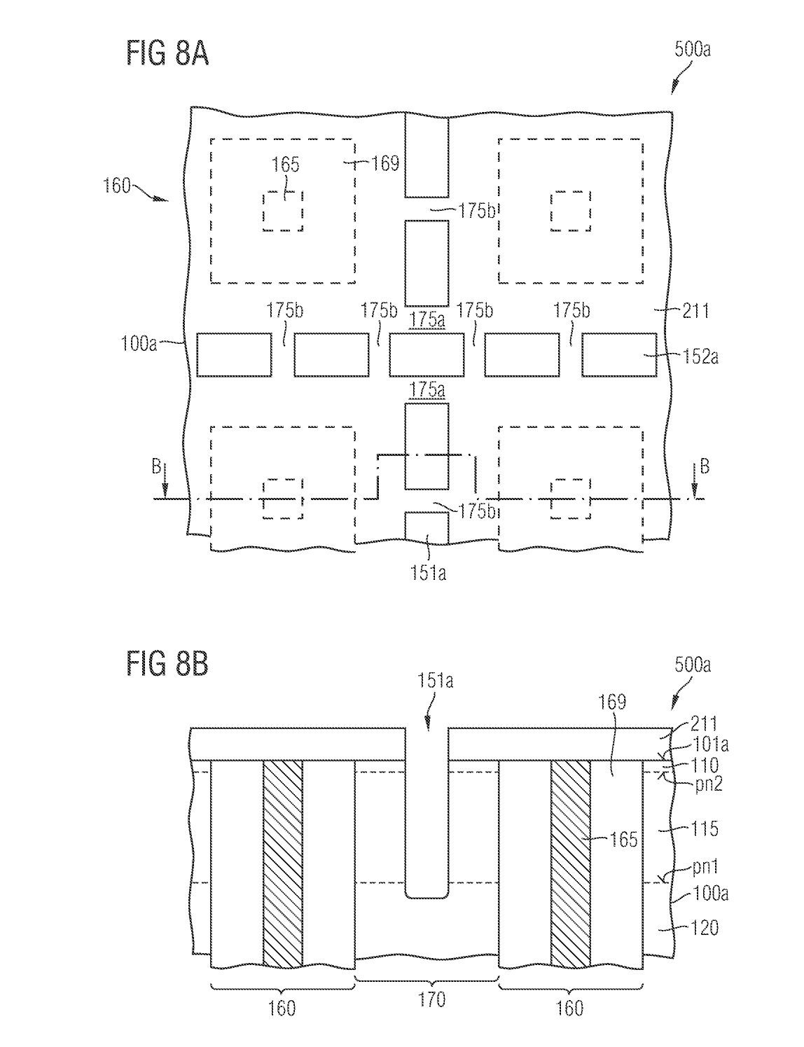

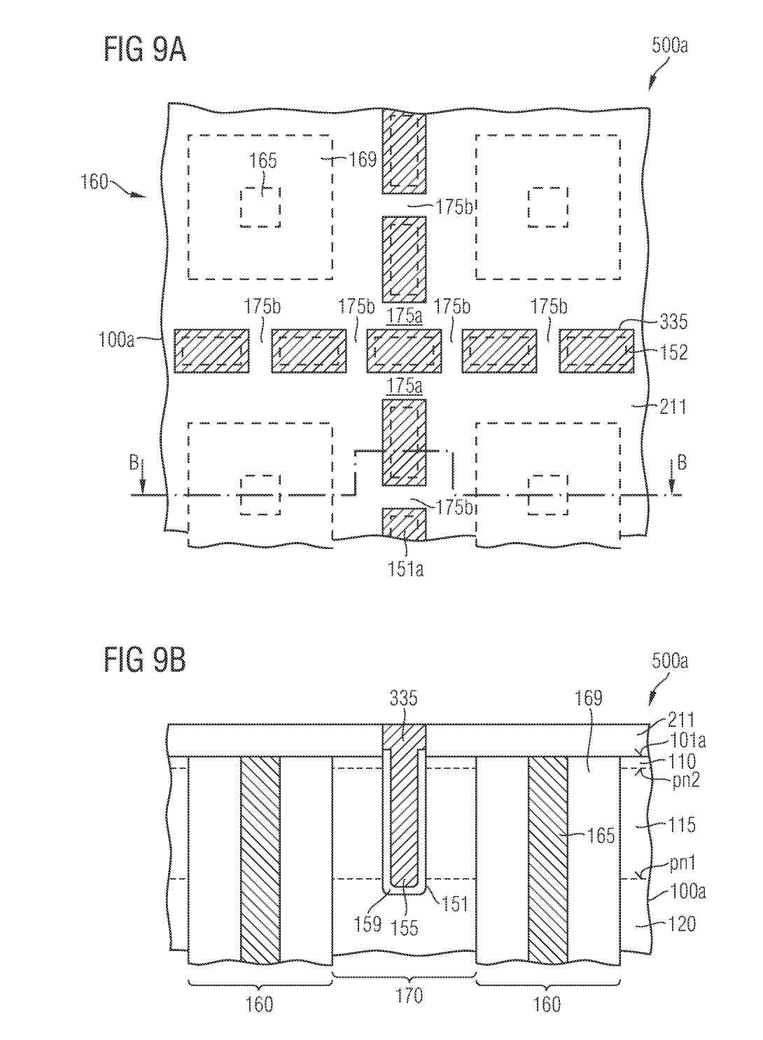

FIGS. 8A and 8B show the patterned pre-metal dielectric layer forming a pre-metal dielectric 211 with gate openings 211a and first and second gate trenches 151a, 152a in the semiconductor layer 100a.

The pre-metal dielectric 211 may include one or more dielectric layers from silicon oxide, silicon nitride, silicon oxynitride, doped or undoped silicate glass, for example BSG, PSG or BPSG.

Remnant portions of the mesa sections 170 between neighboring first and second gate trenches 151a, 152a form first column sections 175a. Remnant portions of the mesa sections 170 between neighboring first gate trenches 151a as well as between neighboring second gate trenches 152a may form second column sections 175b.

A gate dielectric 159 is formed by depositing a dielectric liner or by thermally oxidation of the material of the semiconductor layer 100a. One or more conductive materials, for example a conductive liner containing Ti and/or Ta and a conductive fill material containing W may be deposited, wherein the conductive liner lines the first and second gate trenches 151a, 152a and the conductive fill material fills the first and second gate trenches 151a, 152a. Material deposited outside the gate openings 211a is removed, e.g., by CMP (chemical mechanical polishing).

FIGS. 9A and 9B show a gate electrode 155 in first and second gate fins 151, 152 formed from the conductive materials in the gate trenches 151a, 152a as well as gate contacts 335 formed from the same material in the gate openings 211a of FIGS. 8A and 8B.

A further conductive layer from a conductive material, for example Al, Cu, or W is deposited on the pre-metal dielectric 211. From the further conductive layer, a photolithography process forms a gate wiring 330 in the vertical projection of the first and second gate fins 151, 152.

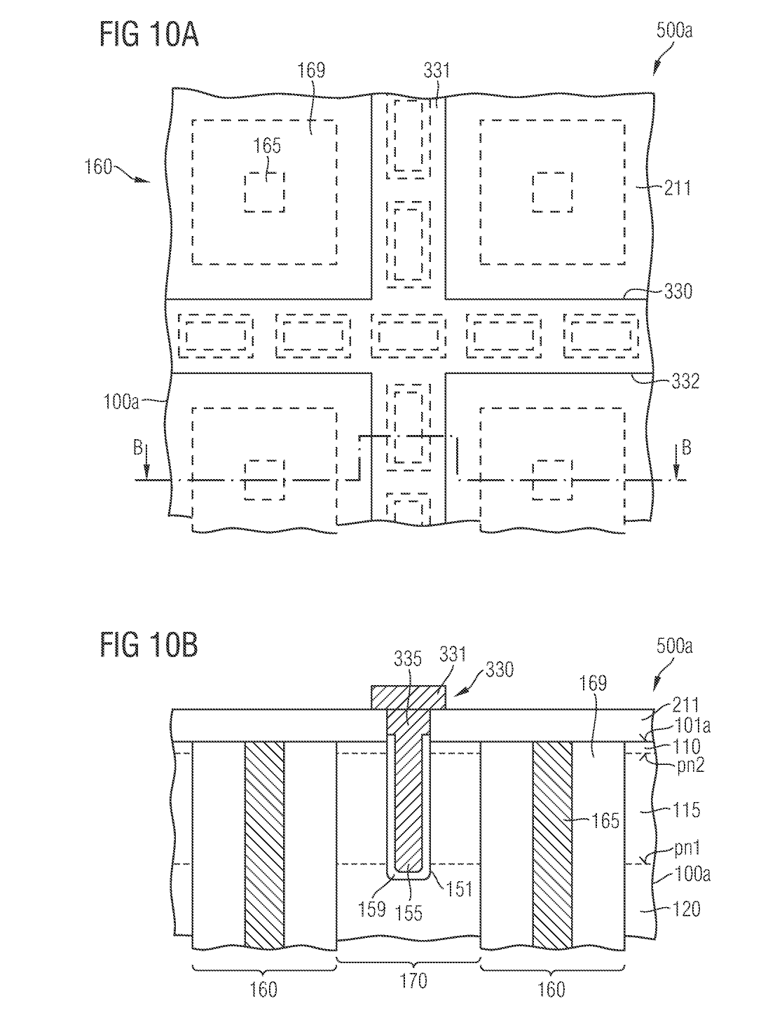

FIGS. 10A and 10B show the gate wiring 330 forming a grid with first wiring sections 331 in the vertical projection of the first gate fins 151 and second wiring sections 132 in the vertical projection of the second gate fins 152. The gate wiring 330 is electrically connected to portions of the gate electrode 155 in both the first and the second gate fins 151a, 152a. An inter-metal dielectric layer 212a is deposited on the process surface 101.

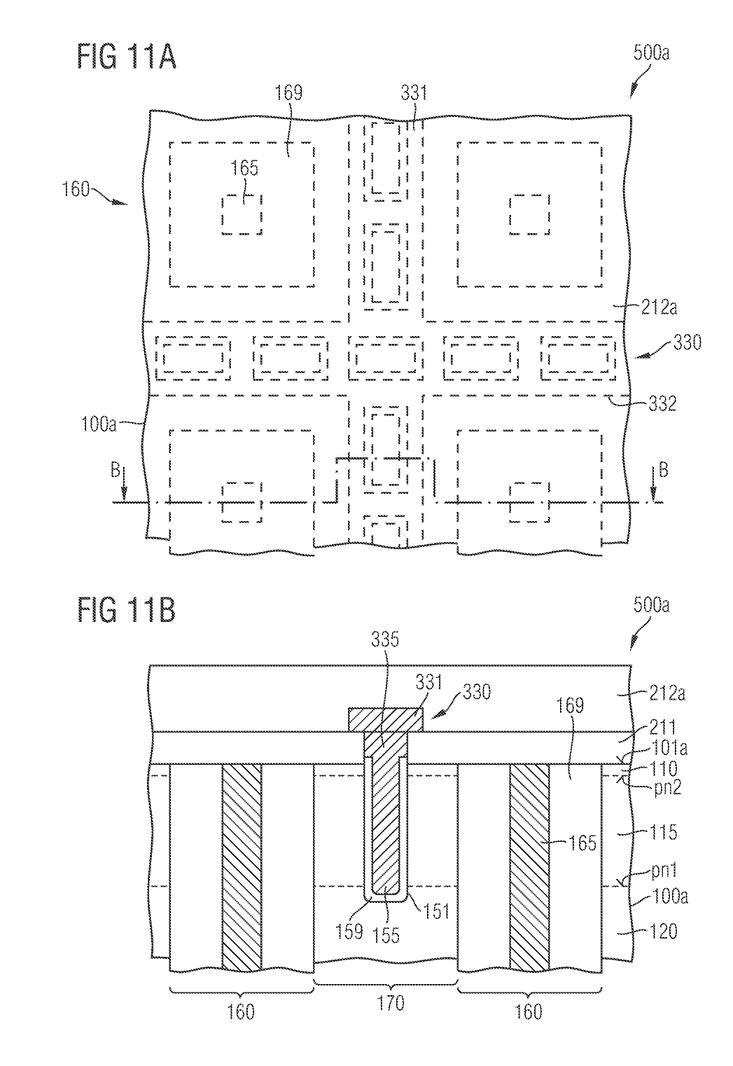

The inter-metal dielectric layer 212a as illustrated in FIGS. 11A and 11B may include one or more dielectric layers from silicon oxide, silicon nitride, silicon oxynitride, doped or undoped silicate glass, for example BSG, PSG or BPSG.

A lithography process forms load contact openings extending through the inter-metal dielectric layer 212a as well as through the pre-metal dielectric 211. Contact grooves may be etched into the semiconductor layer 100a in the vertical projection of the load contact openings to expose portions of the body zones 115, the source zones 110 and the field electrodes 165. Load contact structures 315 are formed that fill the contact grooves in the semiconductor layer 100a and the load contact openings in an interlayer dielectric 210 formed from the pre-metal dielectric 211 and the patterned inter-metal dielectric 212. A further metal layer is deposited on the interlayer dielectric 210 and may be patterned to form a first load electrode 310 electrically connected to the source zones 110, the body zones 115 and the field electrodes 165 through the load contact structures 315 as illustrated in FIGS. 6A to 6C.

From the further metal layer, a gate pad may be formed side-by-side to the first load electrode 310 and intermetal vias extending through the inter-metal dielectric 212 may electrically connect the gate pad with the gate wiring 330.

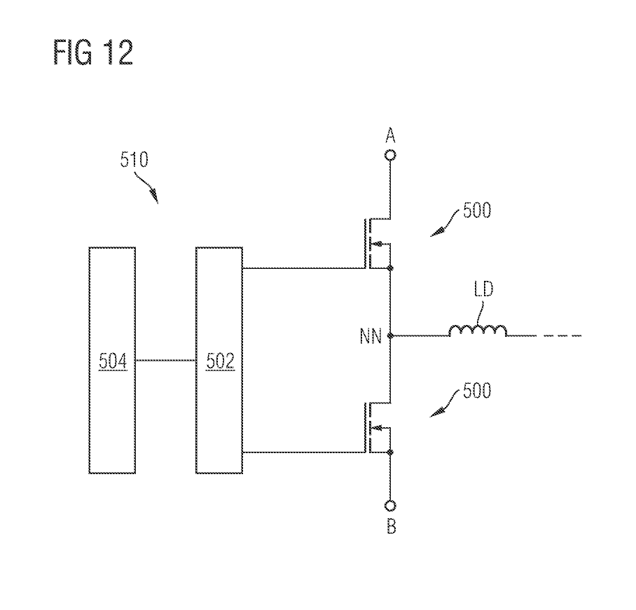

FIG. 12 refers to an electronic assembly 510 that may be a motor drive, a switched mode power supply, a primary stage of a switched mode power supply, a synchronous rectifier, a primary stage of a DC-to-AC converter, a secondary stage of a DC-to-AC converter, a primary stage of a DC-to-DC converter, or a portion of a solar power converter, by way of example.

The electronic assembly 510 may include two identical semiconductor devices 500 as described above. The semiconductor devices 500 may be IGFETs and the load paths of the two semiconductor devices 500 are electrically arranged in series between a first supply terminal A and a second supply terminal B. The supply terminals A, B may supply a DC (direct-current) voltage or an AC (alternating-current) voltage. The network node NN between the two semiconductor devices 500 may be electrically connected to an inductive load, which may be a winding of a transformer or a motor winding, or to a reference potential of an electronic circuit, by way of example. The electronic assembly may further include a control circuit 504 configured to supply a control signal for alternately switching on and off the semiconductor devices 500 and a gate driver 502 controlled by the control circuit 504 and electrically connected to gate terminals of the semiconductor devices 500.

The electronic assembly 510 may be a motor drive with the semiconductor devices 500 electrically arranged in a half-bridge configuration, the network node NN electrically connected to a motor winding and the supply terminals A, B supplying a DC voltage.

According to another embodiment, the electronic assembly 510 may be a primary side stage of a switched mode power supply with the supply terminals A, B supplying an AC voltage of an input frequency to the electronic circuit 510. The network node NN is electrically connected to a primary winding of a transformer.

The electronic assembly 510 may be a synchronous rectifier of a switched mode power supply with the supply terminals A, B connected to a secondary winding of the transformer and the network node NN electrically connected to a reference potential of the electronic circuit at the secondary side of the switched mode power supply.

According to a further embodiment, the electronic assembly 510 may be a primary side stage of a DC-to-DC converter, e.g., a power optimizer or a micro-inverter for applications including photovoltaic cells with the supply terminals A, B supplying a DC voltage to the electronic assembly 510 and the network node NN electrically connected to an inductive storage element.

According to another embodiment, the electronic assembly 510 may be a secondary side stage of a DC-to-DC converter, e.g., a power optimizer or a micro-inverter for applications including photovoltaic cells, wherein the electronic circuit 510 supplies an output voltage to the supply terminals A, B and wherein the network node NN is electrically connected to the inductive storage element.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
gate fins comprising gate electrodes and extending from a first surface into a semiconductor portion, wherein the gate fins are arranged along element lines, longitudinal axes of the gate fins are parallel to the element lines, and column sections of the semiconductor portion separate the gate fins from each other along the element lines.

2. The semiconductor device of claim 1, wherein a distance between neighboring gate fins along the element lines is at least 150 nm.

3. The semiconductor device of claim 1, wherein the semiconductor portion comprises one or more body zones forming one or more first pn junctions with a drift structure and second pn junctions with source zones.

4. The semiconductor device of claim 3, wherein each column section comprises a body column portion of the body zones, and wherein each body column portion is completely depletable when a voltage of 0V is applied between the gate electrodes and the source zones.

5. The semiconductor device of claim 1, further comprising:
field electrode structures extending between neighboring first element lines from the first surface into the semiconductor portion and comprising a field dielectric insulating a field electrode from the semiconductor portion.

6. The semiconductor device of claim 5, wherein the field electrode structures are stripe-shaped and run parallel to the element lines.

7. The semiconductor device of claim 5, wherein the field electrodes are spicular and arranged along electrode lines parallel to the element lines.

8. The semiconductor device of claim 1, wherein the element lines are parallel lines.

9. The semiconductor device of claim 1, wherein the element lines are continuous lines.

10. The semiconductor device of claim 1, wherein the element lines are straight lines.

11. The semiconductor device of claim 1, wherein the element lines comprise first element lines and second element lines intersecting the first element lines, the first and second element lines forming a grid.

12. The semiconductor device of claim 11, wherein the grid comprises straight first element lines parallel to each other and straight, parallel second element lines intersecting the first element lines, and wherein the gate fins comprise first gate fins arranged along the first element lines and second gate fins arranged along the second element lines.

13. The semiconductor device of claim 11, wherein the grid comprises continuous zig-zag first element lines and discontinuous parallel second element lines intersecting the first element lines, and wherein the gate fins comprise first gate fins arranged along the first element lines and second gate fins arranged along the second element lines.

14. The semiconductor device of claim 11, wherein the field electrode structures are formed in meshes of the grid.

15. The semiconductor device of claim 11, wherein the column sections are formed at crossings of the first and second element lines.

16. The semiconductor device of claim 11, wherein at least two first gate fins are formed on each first element line per mesh of the grid.

17. The semiconductor device of claim 11, wherein at least two second gate fins are formed on each second element line per mesh of the grid.

18. The semiconductor device of claim 1, further comprising:
a gate wiring outside the semiconductor portion and comprising wiring sections parallel to the element lines; and
gate contacts that extend through a pre-metal dielectric sandwiched between the gate wiring and the semiconductor portion and that electrically connect the gate wiring with the gate electrodes.

19. The semiconductor device of claim 18, further comprising:
a first load electrode outside the semiconductor portion; and
load contact structures that extend through the pre-metal dielectric and an inter-metal dielectric sandwiched between the first load electrode and the gate wiring,
wherein the load contact structures electrically connect the first load electrode with the field electrodes.

20. A semiconductor device, comprising:
first and second gate fins extending from a first surface into a semiconductor portion, wherein the first gate fins are arranged along first element lines and the second gate fins are arranged along second element lines crossing the first element lines, wherein the first and second gate fins comprise gate electrodes and first column sections of the semiconductor portion separate first gate fins from second gate fins at crossings of the first and second element lines; and
field electrode structures extending from the first surface into the semiconductor portion, the field electrode structures comprising a field dielectric insulating spicular field electrodes from the semiconductor portion.

21. The semiconductor device of claim 20, wherein the field electrode structures are formed in meshes of a grid formed by the first and second element lines.

22. The semiconductor device of claim 20, further comprising:
a gate wiring comprising first wiring sections parallel to the first element lines and second wiring sections parallel to the second element lines; and
gate contacts directly connecting the first wiring sections with gate electrodes in the first gate fins and the second wiring sections with gate electrodes in the second gate fins.

23. The semiconductor device of claim 20, further comprising:
a pre-metal dielectric sandwiched between the gate wiring and the semiconductor portion.

24. A method of manufacturing a semiconductor device, the method comprising:
forming gate fins extending from a process surface into a semiconductor layer and arranged along element lines, wherein the gate fins are separated from each other along the element lines by column sections of the semiconductor layer;
forming gate contacts that extend through a pre-metal dielectric formed on the process surface to gate electrodes formed in the gate fins; and
forming a gate wiring on the pre-metal dielectric, the gate wiring connecting the gate contacts.
